(19) United States
(12) Patent Application Publication
(10) Pub. No.: US 2007/0063745 A1
(43) Pub. Date: Mar. 22, 2007

(54) Support for conditional operations in time-stationary processors

(75) Inventor: Jeroen Anton John Leijten, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., 5621 BA EINDHOVEN (NL)

(21) Appl. No.: 10/552,767

(22) PCT Filed: Apr. 9, 2004
(86) PCT No.: PCT/IB04/50416

§ 371 Date: Oct. 12, 2005

(30) Foreign Application Priority Data
Apr. 16, 2003 (EP) 03101038.2

(51) Int. Cl. H03K 5/01

(52) U.S. Cl. 327/100

(57) ABSTRACT

In case of time-stationary encoding, every instruction that is part of the processor's instruction-set controls a complete set of operations that have to be executed in a single machine cycle. These operations may be processing several different data items traversing the data pipeline. Time-stationary encoding is often used in application-specific processors, since it saves the overhead of hardware necessary for delaying the control information present in the instructions, at the expense of larger code size. A disadvantage of time-stationary encoding is that is does not support conditional operations. The invention proposes to dynamically control the write back of result data to the register file of the timestationary processor, using control information obtained by the program. By controlling the write back of data at run-time, conditional operations can be implemented by a timestationary processor.

The invention relates to a time-stationary processor arranged for execution of a program, the processor comprising: a plurality of execution units, a register file accessible by the execution units, a communication network for coupling the execution units and the register file, and a controller arranged for controlling the processor based on control information derived from the program.

The invention further relates to a method for controlling a time-stationary processor arranged for execution of a program, wherein the processor comprises: a plurality of execution units, a register file accessible by the execution units, a communication network for coupling the execution units and the register file, and a controller arranged for controlling the processor based on control information derived from the program.

Digital signal processing plays an important role in the telecommunications, multimedia and consumer electronics industries. For performing the operations involved in digital signal processing, a special type of processor may be designed, referred to as a digital signal processor. Digital signal processors can be programmable processors or application-specific instruction-set processors. Programmable processors are general-purpose processors and they can be used for manipulating different types of information, including sound, images and video. In case of application specific instruction-set processors, the processor architecture and instruction set is customized, which reduces the system's cost and power dissipation significantly. The latter is crucial for portable and network powered equipment.

Digital signal processor architectures consist of a fixed data path, which is controlled by a set of control words. Each control word controls parts of the data path and these parts may comprise register addresses and operation codes for arithmetic logic units (ALUs) or other functional units. Each set of instructions generates a new set of control words, usually by means of an instruction decoder which translates the binary format of the instruction into the corresponding control word, or by means of a micro store, i.e. a memory which contains the control words directly. Typically, a control word represents a RISC like operation, comprising an operation code, two operand register indices and a result register index. The operand register indices and the result register index refer to registers in a register file.

A Very Large Instruction Word (VLIW) processor is often used for digital signal processing. In case of a VLIW processor, multiple instructions are packaged into one long instruction, a so-called VLIW instruction. A VLIW processor uses multiple, independent execution units to execute these multiple instructions in parallel. The processor allows exploiting instruction-level parallelism in programs and thus executing more than one instruction at a time. Due to this form of concurrent processing, the performance of the processor is increased. In order for a software program to run on a VLIW processor, it must be translated into a set of VLIW instructions. The compiler attempts to minimize the time needed to execute the program by optimizing parallelism. The compiler combines instructions into a VLIW instruction under the constraint that the instructions assigned to a single VLIW instruction can be executed in parallel and under data dependency constraints. The encoding of parallel instructions in a VLIW instruction leads to a severe increase of the code size. Large code size leads to an increase in program memory cost both in terms of required memory size and in terms of required memory bandwidth. In modern VLIW processors different measures are taken to reduce the code size. One important example is the compact representation of no operation (NOP) operations in a data stationary VLIW processor, i.e. the NOP operations are encoded by single bits in a special header attached to the front of the VLIW instruction, resulting in a compressed VLIW instruction.

To control the operations in the data pipeline of a processor, two different mechanisms are commonly used in computer architecture: data-stationary and time-stationary encoding, as disclosed in “Embedded software in real-time signal processing systems: design technologies”, G. Goossens, J. van Praet, D. Lanneer, W. Geurts, A. Kifli, C. Liem and P. Paulin, Proceedings of the IEEE, vol. 85, No. 3, March 1997. In the case of data-stationary encoding, every instruction that is part of the processor's instruction-set controls a complete sequence of operations that have to be executed on a specific data item, as it traverses the data pipeline. Once the instruction has been fetched from program memory and decoded, the processor controller hardware will make sure that the composing operations are executed in the correct machine cycle. In the case of time-stationary coding, every instruction that is part of the processor's instruction-set controls a complete set of operations that have to be executed in a single machine cycle. These operations may be applied to several different data items traversing the data pipeline. In this case it is the responsibility of the programmer or compiler to set up and maintain the data pipeline. The resulting pipeline schedule is fully visible in the machine code program. Time-stationary encoding is often used in application-specific processors, since it saves the overhead of hardware necessary for delaying the control information present in the instructions, at the expense of larger code size.

It is a disadvantage of time-stationary processors that conditional operations, i.e. operations that return a result based on a condition computed at run-time, can not be supported. Time-stationary encoding demands that all control information, including the write back of results to a register file, is statically determined at compile time and encoded in the program.

It is an object of the invention to enable the use of conditional execution of operations in time-stationary processors without the use of jump operations, while maintaining the advantages of time-stationary encoding.

This object is achieved with a processor of the kind set forth, characterized in that the processor is further arranged to dynamically control the transfer of result data from an execution unit of the plurality of execution units to the register file, based on the control information. By dynamically controlling the write back of result data to the register file, it can be determined during run-time if the result data of an operation have to be written back to the register file. As a result, the conditional execution of operations can be implemented on a time-stationary processor, without the use of jump operations.

An embodiment of the invention is characterized in that that the control information comprises an first identifier on the validity of an operation, and wherein the processor is arranged to dynamically control writing of result data corresponding to the operation into the register file, based on the first identifier. In case of an invalid operation, i.e. a so-called NOP operation, no result data have to be written back to the register file. By using the identifier, the writing back of result data is directly disabled in case of an invalid operation.

An embodiment of the invention is characterized in that the first identifier is delayed according to the pipeline of the corresponding execution unit arranged for executing the operation. By delaying the identifier according to the pipeline of the execution unit, the information required for determining the write back of result data becomes available at the output of the execution unit at same time as the result data itself.

An embodiment of the invention is characterized in that the execution unit is arranged to produce a second identifier on the validity of an output result of a corresponding output port of the execution unit, and wherein the processor is further arranged to dynamically control writing of result data corresponding to the operation into the register file, based on both the first identifier and the second identifier. As a result, operations to be executed by the execution unit are allowed that potentially produce more than one valid output.

An embodiment of the invention is characterized in that the processor is further arranged to dynamically control writing of result data corresponding to the operation into the register file, based on the first identifier, the second identifier and an input datum. The input datum represents a true or a false condition, which can be determined in a separate execution unit and subsequently used in other functional units in order to efficiently implement a guarded operation.

An embodiment of the invention is characterized in that the register file is a distributed register file. An advantage of a distributed register file is that it requires less read and write ports per register file segment, resulting in a smaller register file in terms of silicon area. Furthermore, the addressing of a register in a distributed register file requires less bits when compared to a central register file.

An embodiment of the invention is characterized in that the communication network is a partially connected communication network. A partially connected communication network is often less timing critical and less expensive in terms of code size, area and power consumption, when compared to a fully connected communication network, especially in case of a large number of execution units.

According to the invention a method for controlling a processor is characterized in that the method for controlling comprises the step of dynamically controlling the transfer of result data from an execution unit of the plurality of execution units to the register file, using the control information. By dynamically controlling the transfer of result data to an execution unit, it can be decided at run-time if result data have to be written back to the register file, allowing implementing guarded operations by time-stationary encoding.

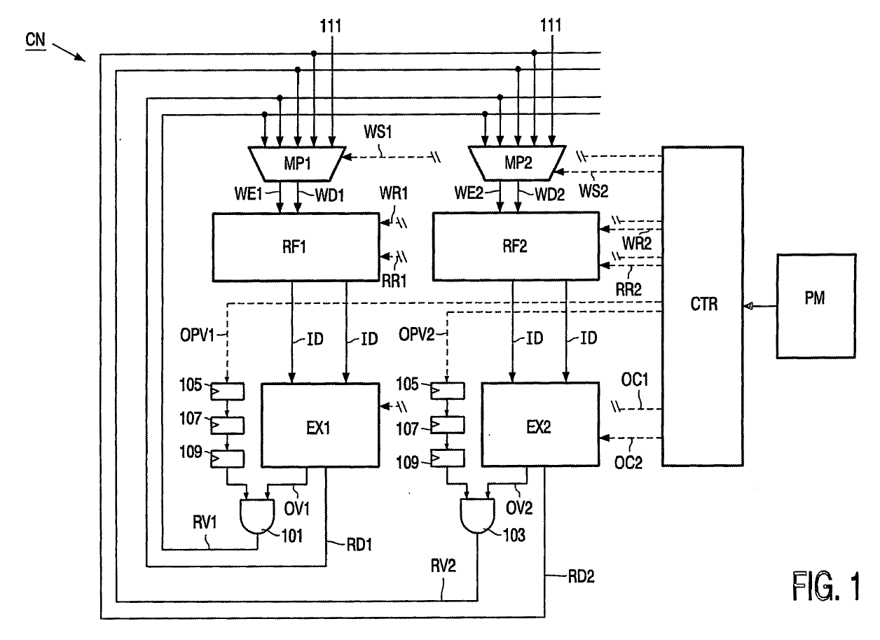

FIG. 1 shows a schematic block diagram of a first VLIW processor according to the invention.

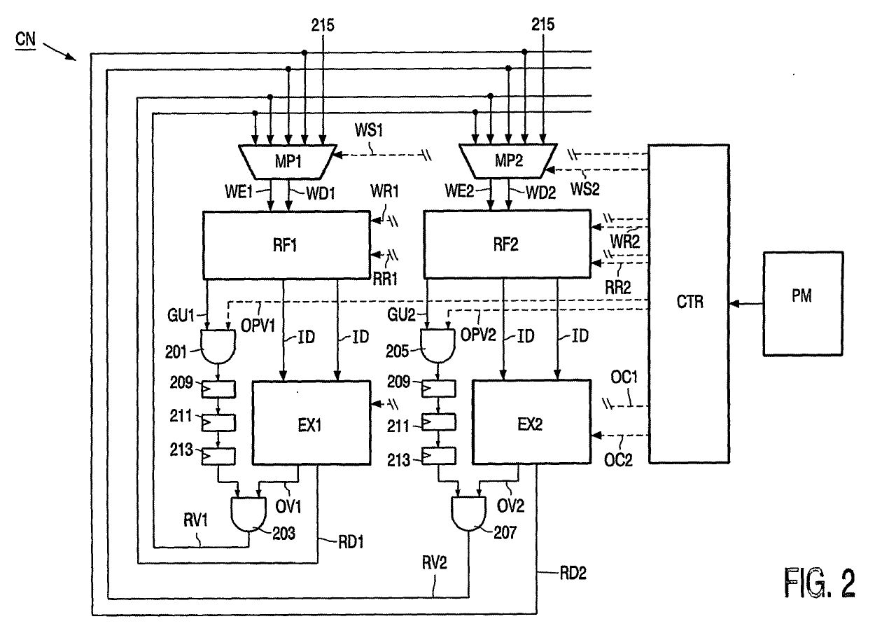

FIG. 2 shows a schematic block diagram of a second VLIW processor according to the invention.

Referring to FIG. 1 and FIG. 2, a schematic block diagram illustrates a VLIW processor comprising a plurality of execution units EX1 and EX2, and a distributed register file, including register file segments RF1 and RF2. The register file segments RF1 and RF2 are accessible by execution units EX1 and EX2, respectively, for retrieving input data ID from the register file. The execution units EX1 and EX2 also are coupled to the register file segments RF1 and RF2 via the communication network CN and multiplexers MP1 and MP2, for passing result data RD1 and RD2 from said execution units to the distributed register file. The controller CTR retrieves instructions from the program memory PM and decodes these instructions. In general, these instructions comprise RISC like operations, requiring only two operands and producing only one result, as well as custom operations that can consume more than two operands and/or that can produce more than one result. Some instructions may require small or large immediate values as operand data. Results of the decoding step are the write select indices WS1 and WS2, write register indices WR1 and WR2, read register indices RR1 and RR2, operation valid indices OPV1 and OPV2, and opcodes OC1 and OC2. Via the couplings between the controller CTR and multiplexers MP1 and MP2, the write select indices WS1 and WS2 are provided to the multiplexers MP1 and MP2, respectively. The write select indices WS1 and WS2 are used by the corresponding multiplexer for selecting the required input channel from the communication network CN for the data WD1 and WD2 that have to be written to register file segments RF1 and RF2, respectively. The write select indices WS1 and WS2 are also used by the corresponding multiplexer for selecting the input channel from the communication network CN for the write enable indices WE1 and WE2 that are used to enable or disable the actual writing of data WD1 and WD2 to the corresponding register file segment RF1 and RF2. The controller CTR is coupled to the register file segments RF1 and RF2 for providing the write register indices WR1 and WR2, respectively, for selecting a register from the corresponding register file segment to which data have to be written. The controller CTR also provides the read register indices RR1 and RR2 to the register file segments RF1 and RF2, respectively, for selecting a register from the corresponding register file segment from which input data ID have to be read by the execution units EX1 and EX2, respectively. The controller CTR is coupled to the execution units EX1 and EX2 as well, for providing the opcodes OC1 and OC2, respectively, that define the type of operation that the execution unit EX1 or EX2 has to perform on the corresponding input data ID. The operation valid indices OPV1 and OPV2 are also provided to execution units EX1 and EX2, respectively, and these indices indicate if a valid operation is defined by the corresponding opcode OC1 or OC2. The value of the operation valid indices OPV1 and OPV2 is determined during decoding of the VLIW instruction. In a prior art time-stationary processor, the write enable indices used for enabling or disabling the writing of data from the execution units to the register file, are statically determined, since they are encoded in the program at compile time. The controller obtains the write enable indices from the program after decoding, and directly provides the write enable indices to the register file.

Referring to FIG. 1, the controller CTR is coupled to registers 105. The controller CTR derives operation valid indices OPV1 and OPV2 from the program during the decoding step and these operation valid indices are provided to the registers 105. In case the encoded operation is a NOP operation, the operation valid index is set to false, otherwise the operation valid index is set to true. The operation valid indices OPV1 and OPV2 are delayed according to the pipeline of the corresponding execution unit EX1 and EX2 using registers 105, 107 and 109. After execution of the operations by execution unit EX1 and EX2, as defined via opcodes OC1 and OC2 respectively, the corresponding result data RD1 and RD2 as well as the corresponding output valid indices OV1 and OV2 are produced. The output valid index OV1 or OV2 is true if the corresponding result data RD1 or RD2 are valid, otherwise it is false. Unit 101 performs a logic AND on the delayed operation valid index OPV1 and the output valid index OV1, resulting in a result valid index RV1. Unit 103 performs a logic AND on the delayed operation valid index OPV2 and the output valid index OV2, resulting in a result valid index RV2. The units 101 and 103 are both coupled to multiplexers MP1 and MP2, via the partially connected network CN, for passing the result valid indices RV1 and RV2 to the multiplexers MP1 and MP2. The write select indices WS1 and WS2 are used by the corresponding multiplexers MP1 and MP2 to select a channel from the connection network CN from which result data have to be written to the corresponding register file segment. In case a result data channel is selected by a multiplexer, the result valid indices RV1 and RV2 are used to set the write enable indices WE1 and WE2, for control of writing result data RD1 and RD2 to the register file segments RF1 and RF2, respectively. In case multiplexer MP1 or MP2 has selected the input channel corresponding to result data RD1, result valid RV1 is used for setting the write enable index corresponding to that multiplexer, and in case the input channel corresponding to result data RD2 is selected, result valid index RV2 is used for setting the corresponding write enable index. If result valid index RV1 or RV2 is true, the appropriate write enable index WE1 or WE2 is set to true by the corresponding multiplexer MP1 and MP2. In case the write enable index WE1 or WE2 is equal to true, the result data RD1 or RD2 are written to the register file segment RF1 or RF2, in a register selected via the write register index WR1 or WR2 corresponding to that register file segment. In case the write enable index WE1 or WE2 is set to false, though via the corresponding write select index WS1 or WS2 an input channel for writing data to corresponding register file segment RF1 or RF2 has been selected, no data will be written into that register file segment. In order to disable the write back of any result data RD1 or RD2 via a given write port of register file segments RF1 and RF2, respectively, the write select index WS1 or WS2 corresponding to that register file segment can be used to select the default input 111 from the corresponding multiplexer MP1 or MP2, in which case no result data are written to that register file segment.

Referring to FIG. 2, the controller CTR is coupled to logic units 201 and 205. The controller CTR retrieve operation valid indices OPV1 and OPV2 from the program during the decoding step and these operation valid indices are provided to logic unit 201 and 205, respectively. In case the encoded operation is a NOP operation, the operation valid index is set to false, otherwise the operation valid index is set to true. The register file segments RF1 and RF2 are coupled to unit 201 and 205 respectively, and the corresponding guards GU1 and GU2 can be written from the register file segments RF1 and RF2 to the units 201 and 205, respectively. The guards GU1 and GU2 can be either true or false, depending on the outcome of the operation during which the value of that guard was determined. Units 201 and 205 perform a logic AND on the corresponding operation valid index OPV1 or OPV2, and the corresponding guard GU1 or GU2. The resulting index is delayed according to the pipeline of the corresponding execution unit EX1 and EX2 using registers 209, 211 and 213. After the operation, defined via opcode OC1 or OC2, has been executed by execution unit EX1 and EX2, respectively, the corresponding result data RD1 and RD2 as well as the corresponding output valid index OV1 and OV2 are produced. The output valid indices OV1 and OV2 are true if the corresponding result data RD1 or RD2 are valid output data, otherwise they are false. Unit 203 performs a logic AND on the delayed index, resulting from guard GU1 and operation valid index OPV1, and the output valid index OV1, resulting in a result valid index RV1. Unit 207 performs a logic AND on the delayed index, resulting from guard GU2 and operation valid index OPV2, and the output valid index OV2, resulting in a result valid index RV2. The units 203 and 207 are coupled to multiplexers MP1 and MP2, respectively, via the partially connected network CN, for passing the result valid indices RV1 and RV2 to multiplexers MP1 and MP2. The result valid indices RV1 and RV2 are used to set the write enable index WE1 or WE2 for control of writing result data RD1 or RD2 to the register file segments RF1 and RF2. The write select indices WS1 and WS2 are used by the corresponding multiplexers MP1 and MP2 to select a channel from the connection network CN from which result data have to be written to the corresponding register file segment. In case a result data channel is selected by a multiplexer, the result valid indices RV1 and RV2 are used to set the write enable indices WE1 and WE2, for control of writing result data RD1 and RD2 to the register file segments RF1 and RF2, respectively. In case multiplexer MP1 or MP2 has selected the input channel corresponding to result data RD1, result valid RV1 is used for setting the write enable index corresponding to that multiplexer, and in case the input channel corresponding to result data RD2 is selected, result valid index RV2 is used for setting the corresponding write enable index. If result valid index RV1 or RV2 is true, the appropriate write enable index WE1 or WE2 is set to true by the corresponding multiplexer MP1 and MP2. In case the write enable index WE1 or WE2 is equal to true, the result data RD1 or RD2 are written to the register file segment RF1 or RF2, in a register selected via the write register index WR1 or WR2 corresponding to that register file segment. In case the write enable index WE1 or WE2 is set to false, though via the corresponding write select index WS1 or WS2 an input channel for writing data to corresponding register file segment RF1 or RF2 has been selected, no data will be written into that register file segment. In order to disable the write back of any result data RD1 or RD2 via a given write port of register file segments RF1 and RF2, respectively, the write select index WS1 or WS2 corresponding to that register file segment can be used to select the default input 111 from the corresponding multiplexer MP1 or MP2, in which case no result data are written to that register file segment.

The time-stationary VLIW processors according to FIG. 1 and FIG. 2 allow dynamically controlling the write back of result data to the register file. It can be determined during run-time if the result data of an operation that has been executed have to be written back to the register file. As a result, conditional operations can be implemented by a processor using time-stationary encoding of instructions.

Below an example of a piece of program code is shown, that should be executed by a time-stationary processor according to the invention. In this program code the letters A, B0, B1, B2, C0, C1 and D refer to statements and X to a condition that can either be false or true.

.
.
A;
if (X) then
{
B0; B1; B2;
}
else
{
C0; C1;
}
D;
.
.

The program code can be executed by a processor according to FIG. 2 as follows. The program code is converted by the compiler using a well-known technique called “if conversion”, which allows the execution of if-then-else bodies without the need for costly branching. Because of this, it even allows the parallel execution of “if-then-else” bodies by ensuring that either the “then” or the “else” body returns results based on the “if” condition or its complement used as guard for the instruction(s) in the “then” and “else” bodies. Using “if conversion” the above shown piece of program code is converted to:

```
    .
.
A;
    if (X): B0;
    if (X): B1;
    if (X): B2;
    if (!X): C0;
    if (!X): C1;
    D;
    .
    .
```

Referring to FIG. 2, an instruction is executed by either execution unit EX1 or EX2 to determine the value of condition X. This instruction produces the result “true”, and this result is stored in register file segment RF1 and its complement, i.e. the result “false”, is stored in register file segment RF2. Next, execution unit EX1 executes instructions comprising statements B0, B1 and B2, and execution unit EX2 executes instructions comprising statements C0 and C1. Because of the removal of the control flow in the if-converted program, which is normally implemented using jump operations and therefore sequential in nature, operations in the “then” and “else” bodies of the original program can now be scheduled in parallel, if data dependencies and availability of resources permit to do so. The controller CTR decodes the VLIW instruction, and sends the resulting write select indices WS1 and WS2 to the corresponding multiplexers MP1 and MP2, the write register indices WR1 and WR2 as well as read register indices RR1 and RR2 to the corresponding register file segments RF1 and RF2, the operation codes OC1 and OC2 to the corresponding execution units EX1 and EX2 and the operation valid indices OPV1 and OPV2 to the corresponding unit 201 and 205. These operation valid indices OPV1 and OPV2 are equal to “true”. The units 201 and 205 also receive the result of the evaluation of statement X or its complement, respectively, as a corresponding guard GU1 and GU2, and perform a logic AND of the guard and the operation valid index. In case of unit 201 the logic AND will produce “true” as a result, while in case of unit 205 the logic AND will produce “false” as a result, since the guards GU1 and GU2 are equal to true and false, respectively. While statements B0, B1, B2, C1 or C2 are executed by execution units EX1 and EX2 respectively, the results of the logic AND are clocked through the registers 209, 211 and 213. Both for execution unit EX1 and EX2 the corresponding output valid indices OV1 and OV2 are equal to true. Unit 203 will perform a logic AND of the operation valid OV1 and the result of the logic AND performed by unit 201. The result of this logic AND will be true, and therefore result valid index RV1 is equal to true. Via partially connected network CN, the value of result valid index RV1 as well as the corresponding result data RD1 are transferred to multiplexers MP1 and MP2. Using the write select index WS1, the multiplexer MP1 selects the input channel corresponding to result data RD1. The write enable index WE1 is subsequently set to true using result valid index RV1, and the result data RD1 are written to register file segment RF1 as data WD1. Unit 207 will perform a logic AND of the operation valid OV2 and the result of the logic AND performed by unit 205. The result of this logic AND will be false, and therefore result valid index RV2 is equal to false. Via partially connected network CN, the value of result valid index RV2 as well as the result data RD2 are transferred to multiplexers MP1 and MP2. Using the write select index WS2, the multiplexer MP2 selects the channel corresponding to result data RD2. The write enable index WE2 is subsequently set to false using result valid index RV2, and so the result data RD2 are not written to register file segment RF2. Alternatively, the value of guard X and its complement can be stored in both register file segment RF1 and register file segment RF2. Now statements B0, B1, B2, C0 and C1 can be executed by both execution unit EX1 and execution unit EX2. In case execution unit EX1 or EX2 is executing statements B0, B1 or B2 the value of X is used for guard GU1 or GU2, respectively. If execution unit EX1 or EX2 is executing statements C0 or C1 the complement of X is used for guard GU1 or GU2, respectively. As a result, when executing statements B0, B1 or B2 the result date RD1 or RD2 are written to register file segment RF1 and/or RF2. If statements C0 or C1 are executed, the result data RD1 or RD2 are not written to register file segment RF1 and/or RF2.

Below another example of a piece of program code is shown, that should be executed by a time-stationary processor according to the invention. In this program code the letters Z, P and Q refer to variables and X to a condition that can either be false or true. When executing this program fragment, the value of P and Q are added, and the result is assigned to Z, if condition X is equal to true.

```
        .
        .
if (X) then
        {
        Z = add (P, Q);
        }
        .
        .
```

The program code can be executed by a processor according to FIG. 1 as follows. The program code is converted by the compiler and the add operation is replaced by a conditional add operation, cadd, taking the value of condition X as an additional argument:

.
.
Z = cadd (X, P, Q);
.
.

Referring to FIG. 1, an instruction is executed by either execution unit EX1 or EX2 to determine the value of condition X. This instruction produces the result “true”, and this result is stored in register file segment RF1. The value of parameters P and Q are stored in register file segment RF1 as well. The cadd instruction is executed by execution unit EX1. The value of condition X, as well as parameters P and Q are received as input data ID by execution unit EX1. During execution of instruction cadd, the value of condition X is evaluated by execution unit EX1 and if this value is equal to true, the output valid index OV1 is set equal to true. In case the value of condition X is equal to false, the output valid index OV1 is set equal to false. In this example, the value of condition X is equal to true, and therefore the value of output valid index OV1 is set equal to true as well. Furthermore, execution unit EX1 calculates the value of parameter Z. Unit 101 performs a logic and on the operation valid index OPV1 corresponding to instruction cadd and the output valid index OV1. Since the operation valid index OPV1 is equal to true, the resulting result valid index RV1 is equal to true as well. The result valid index RV1 and the result data RD1, in the form of the value of parameter Z, are transferred to multiplexers MP1 and MP2 via partially connected network CN. Using write select index WS1, multiplexer MP1 selects the channel corresponding to result data RD1 as input channel. Multiplexer MP1 sets the write enable index WE1 equal to true using result valid index RV1, and the value of parameter Z is written to register file segment RF1 as write data WD1. In case the condition X is equal to false, the output valid index OV1 is set to false by execution unit EX1. The logic AND performed by unit 101 results in a result valid index RV1 equal to false. As a result, the write enable index WE1 is set to false. In this case the value of parameter Z is not written to register file segment RF1.

The above examples show that the conditional execution of operations in time-stationary processors without the use of jump operations can be implemented, by dynamically controlling the transfer of result data from an execution unit to a register file.

In another embodiment the communication network CN may be a partially connected communication network, i.e. not every execution unit EX1 and EX2 is coupled to all register file segments RF1 and RF2. In case of a large number of execution units, the overhead of a fully connected communication network will be considerable in terms of silicon area, delay and power consumption. During design of the VLIW processor it is decided to which degree the execution units are coupled to the register file segments, depending on the range of applications that has to be executed.

In another embodiment the distributed register file, comprising register file segments RF1 and RF2, is a single register file. In case the number of execution units of a VLIW processor is relatively small, the overhead of a single register file is relatively small as well.

In another embodiment, the VLIW processor may have more execution units. The number of execution units depends on the type of applications that the VLIW processor has to execute, amongst others. The processor may also have more register file segments, connected to said execution units.

In another embodiment, the execution units EX1 and EX2 may have multiple inputs and/or multiple outputs, depending on the type of operations that the execution units have to perform, i.e. operations that require more than two operands and/or produce more than one result. The register file may also have multiple read and/or write ports per register file segment.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

1. A time-stationary processor arranged for execution of a program, the processor comprising:
a plurality of execution units;
a register file accessible by the execution units;
a communication network for coupling the execution units and the register file;
a controller arranged for controlling the processor based on control information derived from the program,
characterized in that the processor is further arranged to dynamically control the transfer of result data from an execution unit of the plurality of execution units to the register file, based on the control information.

2. A processor according to claim 1, characterized in that the control information comprises a first identifier on the validity of an operation, and wherein the processor is arranged to dynamically control writing of result data corresponding to the operation into the register file, based on the first identifier.

3. A processor according to claim 2, characterized in that the first identifier is delayed according to the pipeline of the corresponding execution unit arranged for executing the operation.

4. A processor according to claim 1, characterized in that the execution unit is arranged to produce a second identifier on the validity of an output result of a corresponding output port of the execution unit, and wherein the processor is further arranged to dynamically control writing of result data corresponding to the operation into the register file, based on both the first identifier and the second identifier.

5. A processor according to claim 4, characterized in that the processor is further arranged to dynamically control writing of result data corresponding to the operation into the register file, based on the first identifier, the second identifier and an input datum.

6. A processor according to claim 1, characterized in that the register file is a distributed register file.

7. A processor according to claim 1, characterized in that the communication network is a partially connected communication network.

8. A method for controlling a time-stationary processor arranged for execution of a program, wherein the processor comprises:
a plurality of execution units;
a register file accessible by the execution units;
a communication network for coupling the execution units and the register file;
a controller arranged for controlling the processor based on control information derived from the program,
characterized in that the method for controlling comprises the step of dynamically controlling the transfer of result data from an execution unit of the plurality of execution units to the register file, using the control information.
